(19) United States
(12) Patent Application Publication
(10) Pub. No.: US 2025/0348003 A1
(43) Pub. Date: Nov. 13, 2025

(54) Apparatus and Method for Lithographic Exposure of Large Area Substrates

(71) Applicant: ZS Systems LLC, Lafayette, IN (US)

(72) Inventor: Sergey Zakharov, Lafayette, IN (US)

(21) Appl. No.: 18/661,503

(22) Filed: May 10, 2024

(51) Int. Cl. G03F 7/20; G03F 7/00

(52) U.S. Cl. CPC G03F 7/201; G03F 7/2022; G03F 7/70291; G03F 7/70358; G03F 7/705; G03F 7/7085

(57) ABSTRACT

This application is directed to controlling a manufacturing process (e.g., related to semiconductor devices, additive nano- and micro-fabrication, etc.). Relative motion is created between a substrate and a radiation system in a predetermined direction. A first position of the substrate is measured at a first time using a sensor at a first sampling rate, and applied to generate a series of expected positions of the substrate at a second sampling rate that is higher than the first sampling rate. A second position of the substrate corresponds to a second time later than the first time, and is determined based on the series of expected positions. A radiation operation is controlled at the second time to process the substrate, e.g., to expose a selected active area of the substrate for a predetermined duration of time.

### GOVERNMENT RIGHTS

The subject matter of the invention may be subject to U.S. Government Rights under National Science Foundation grants: NSF SBIR Phase 1 Grant No. 2127879 and NSF SBIR Phase 2 Grant No. 2322184.

### TECHNICAL FIELD

This application relates generally to micro- and nano-fabrication, lithography, and stereolithography, including, but not limited to, methods, systems, and devices for implementing customized radiation exposure operations on radiation sensitive substrates.

### BACKGROUND

Synchronization of substrate position and optical exposure poses critical challenges in semiconductor lithographic devices. Precise coordination between movement of a substrate and projection of light patterns onto its surface is essential for achieving accurate patterning at nanoscale levels. However, achieving this synchronization is complex due to various factors such as mechanical vibrations, thermal fluctuations, and control system latencies. These issues can result in misalignment between an intended pattern and an actual pattern formed on the substrate, leading to defects in devices being fabricated. As such, engineers continually strive to develop advanced control algorithms and hardware solutions to mitigate these synchronization challenges and enhance an overall accuracy and efficiency of semiconductor lithography-based manufacturing processes.

### SUMMARY

Various embodiments of this application are directed to image printing methods, systems, and devices for implementing lithographic and stereolithographic exposures on a wide range of substrates, including but not limited to round wafers, square wafers, and rectangular substrates having large areas or high aspect ratios, e.g., long and thin substrates. In some embodiments, constant relative motion may be created between a substrate and a radiation system and sampled to predict positions of the substrate with a higher sampling rate. Based on the predicted positions of the substrate, radiation operations are controlled to process active areas or subareas on the substrate. In some embodiments, the relative motion has a constant velocity or a constant acceleration along or in a predefined direction. In some embodiments, each active area includes two or more subareas that are separately processed in two series of radiation operations corresponding to two distinct patterns (e.g., provided by a fixed reticle, a programmable spatial radiation modulator (PSRM), or a combination of one or more reticles and PSRMs). In some embodiments, a radiation projection device (e.g., which includes a PSRM and a radiation source) is applied to expose different active areas or subareas with different patterns, thereby creating custom non-periodic patterns at different active areas or subareas. By these means, radiation operations are precisely and efficiently implemented and optimized to create any micro- or nano-structures at high throughput that may have a varying, repeated, or mixed patterns on the substrate.

In one aspect, a method is implemented at an apparatus for controlling a manufacturing process. The method includes creating relative motion between a substrate and a radiation system in a predetermined direction (generally a straight line), measuring a first position of the substrate at a first time using a sensor at a first sampling rate, and generating a series of expected positions of the substrate at a second sampling rate based on the first position. The second sampling rate is higher than the first sampling rate. The method further includes determining a second position of the substrate corresponding to a second time later than the first time based on the series of expected positions. The substrate is configured to be processed by a radiation operation (e.g., irradiated) at the second time.

In some embodiments, the first position of the substrate is measured with respect to the radiation system. The method further includes determining a first speed and a first acceleration of the relative motion between the substrate and the radiation system at the first time. The series of expected positions are generated based on the first position, the first speed, the first acceleration, and optionally the first jerk.

In some embodiments, creating the relative motion further includes driving the radiation system to move in the predetermined direction and driving the substrate to move in another direction that is orthogonal to the predetermined direction. The substrate has a dimension in the direction substantially parallel to the predetermined direction that is substantially larger than the substrate's dimension in the direction substantially parallel to the direction that is orthogonal to the predetermined direction.

In some embodiments, the substrate has a plurality of active areas that are aligned along a straight line substantially parallel to the predetermined direction. Determining the second position of the substrate further includes, for each of the series of expected positions, determining whether the respective expected position matches one of a plurality of known positions in the predetermined direction; and in accordance with a determination that the respective expected position matches a respective known position, identifying the respective expected position as the second position and identifying the second time that is later than the first time and corresponds to the second position.

In some embodiments, the method further includes, in response to detecting the second position of the substrate at the second time, implementing the radiation operation (e.g., irradiating the substrate) including controlling a radiation source by a radiation control signal to generate radiation that exposes a corresponding active area of the substrate for a predetermined duration of time. Further, in some embodiments, the radiation source provides respective patterned radiation exposure on the corresponding active area during the predetermined duration of time, and the radiation source includes a light source and a programmable PSRM of an amplitude and/or phase type. Implementing the radiation operation further includes, a PSRM spatially modulating light generated by the light source to provide the respective patterned radiation exposure. In some embodiments an ultraviolet (UV) or extreme ultraviolet (EUV) radiation source is used as a light source.

Some implementations of this application include an apparatus. The apparatus includes a sensor for measuring a first position of a substrate at a first time at a first sampling rate and a controller coupled to the sensor. The controller is configured to perform any of the above methods. For example, the controller is configured to create relative motion between a substrate and a radiation system in a predetermined direction; control the sensor to measure a first position of a substrate at a first time at a first sampling rate; generate, based on the first position, a series of expected positions of the substrate at a second sampling rate higher than the first sampling rate; and determine a second position of the substrate corresponding to a second time later than the first time based on the series of expected positions. The substrate is configured to be processed by a radiation operation at the second time. In some embodiments, the apparatus further includes one or more of: a radiation system, one or more reticles, a radiation projection system, a relay system with pre-scaler, and a programmable PSRM.

As used herein, the term “active area” is also called “exposure area.” It is also noted that, in some implementations, a position, movement, speed, or acceleration of a substrate is measured relative to that of the radiation system.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a schematic diagram showing an arrangement of a substrate processing system (e.g., a lithographic stepper, or stereolithographic 3D printer) for implementing one or more scaled patterned exposures on a substrate, in accordance with some embodiments.

FIG. 2 is a block diagram of an example control system for synchronizing substrate movement and a radiation operation, in accordance with some embodiments.

FIG. 3A is a top view of an example where substrate moves with reference to a radiation system, in accordance with some embodiments.

FIGS. 3B and 3C are top views of a portion of an example substrate configured to be processed by a series of radiation operations, in accordance with some embodiments.

FIGS. 4A-4C are three diagrams illustrating three sets of neighboring active areas and associated optical arrangements, in accordance with some embodiments.

FIG. 5A is a top view of a substrate having at a plurality of structured active areas each of which further includes a plurality of subareas, in accordance with some embodiments.

FIG. 5B shows an example of an active area being composed of nine subareas, in accordance with some embodiments.

FIG. 5C is an example of a reticle which can be used to produce active area shown in FIG. 5B in accordance with arrangement, in accordance with some embodiments.

FIG. 5D is a diagram illustrating a set of identical neighboring active areas and two associated reticle arrangements, in accordance with some embodiments.

FIG. 6A is a diagram illustrating a set of distinct neighboring active areas 304 and an associated optical arrangement, in accordance with some embodiments.

FIG. 6B is a top view of an example substrate having a plurality of active areas distributed along an extended length of the substrate, in accordance with some embodiments.

FIGS. 6C and 6D are diagrams illustrating two example optical encoder grating substrates, in accordance with some embodiments.

FIGS. 7A and 7B are diagrams illustrating a set of identical neighboring active areas and two associated split mask arrangements, in accordance with some embodiments, respectively.

FIG. 8 is a top view of an example substrate having a large aspect ratio, and being processed by the processing system, in accordance with some embodiments.

FIG. 9 is a flow diagram of an example lithographic irradiation method, in accordance with some embodiments.

Like reference numerals refer to corresponding parts throughout the several views of the drawings.

### DETAILED DESCRIPTION

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic devices using secondary storage.

In accordance with at least some embodiments disclosed herein is the realization that high-speed position sensing and synchronization of substrate position and radiation exposure poses critical challenges in design of lithographic equipment for use in additive manufacturing, semiconductor device fabrication, advanced packaging of semiconductor devices, flat panel manufacturing, sensor production, and other industries. Precise coordination between movement of a substrate and projection of radiation patterns onto the substrate is essential for achieving accurate printing of patterns at nanoscale levels. However, achieving this synchronization is complex due to various factors such as mechanical vibrations, thermal fluctuations, and control system latencies. These issues can result in misalignment between an intended pattern and an actual pattern printed on the substrate, leading to defects in devices being fabricated. Precision position sensors are used for synchronizing and controlling the motion. In some embodiments, position sensors are limited to the sampling rates of several dozens of MHz. At the same time, increasing demand on equipment throughput, combined with miniaturization of printed features, requires synchronization solutions capable to operate at frequencies of 1 GHz and higher.

In accordance with at least some embodiments disclosed herein is the realization that traditional wafer steppers solve these issues by moving both the substrate and reticle while synchronizing their velocities instead positions. This approach requires returning the reticle to its original position after processing every active area (or die) and faces additional limitations due-to a fixed reticle size: it is unable to produce devices with uninterrupted features spanning the full size of a wafer. Additional challenges arise when there is a need to produce large size devices exceeding the size of an industry standard 300 mm diameter wafer, and no commercially available equipment exists to produce micro- and nano-patterns on large-size large aspect ratio substrates, while products such as graduated encoder scales might be for example 3200 mm long by 12 mm wide. Some implementations of this application are directed to advanced control algorithms and hardware solutions, which mitigate the synchronization challenges and enhance overall capabilities, accuracy, resolution, efficiency, and throughput of the micro- and nanofabrication equipment.

Various embodiments of this application are directed to methods and apparatuses for implementing lithographic and/or stereolithographic exposures on substrates (e.g., round wafers, square, or rectangular substrates having high aspect ratios) and forming repeated, custom, or mixed active areas on the substrates. Substrate is covered by a layer of radiation sensitive material and lithographic exposures includes selective polymerization of a radiation sensitive material. Produced pattern can be used as a mask to etch underlaying layers, or as a mask to deposit additional layers in according with one or more methods well known in the arts. In some embodiments micro and nano particles can be suspended in the radiation sensitive material, and fused together in the areas patterned by the lithographic exposure after curing at elevated temperatures. Pattern of fused particles can be also used as a mask to etch underlaying layers, or as a mask to deposit additional layers. Multiple layers can be exposed in a stereolithographic exposure to additively manufacture three-dimensional parts. These are a few examples of many applications of lithographic exposure known to those skilled in the art and benefiting from the current invention.

In some embodiments, a constant relative motion is created between a substrate and a radiation system and sampled to predict positions of the substrate with a higher sampling rate. In some embodiments, the relative motion has a constant velocity along a predefined direction covering the entire length of the substrate, while acceleration and deceleration occur outside of the substrate bounds. No start/stop operations typical of a step-and-repeat wafer stepper are performed, regardless of a number of active areas (or dies) being exposed. In some embodiments, the relative motion has a constant acceleration and deceleration along a predefined direction within the bounds of the substrate. Based on the measured positions of the substrate, pulsed radiation operations are controlled to process active areas on the substrate. In some embodiments, a projection device (which includes a PSRM and a radiation source) is applied to expose different active areas with the same pattern via a first series of radiation operations, thereby creating repeated patterns on different active areas. In some embodiments, a projection device (which includes a PSRM and a radiation source) is applied to expose part of different active areas with different patterns via a second series of radiation operations, thereby creating custom non-periodic patterns among different active areas. In some embodiments, each active area includes two or more subareas that are separately processed in two series of radiation operations corresponding to two distinct patterns, allowing the subareas of each active area to combine a repeated pattern and a custom pattern. By these means, in some embodiments, radiation operations are implemented to create micro- or nano-structures that have different types of patterns on the substrate precisely, efficiently, and inexpensively.

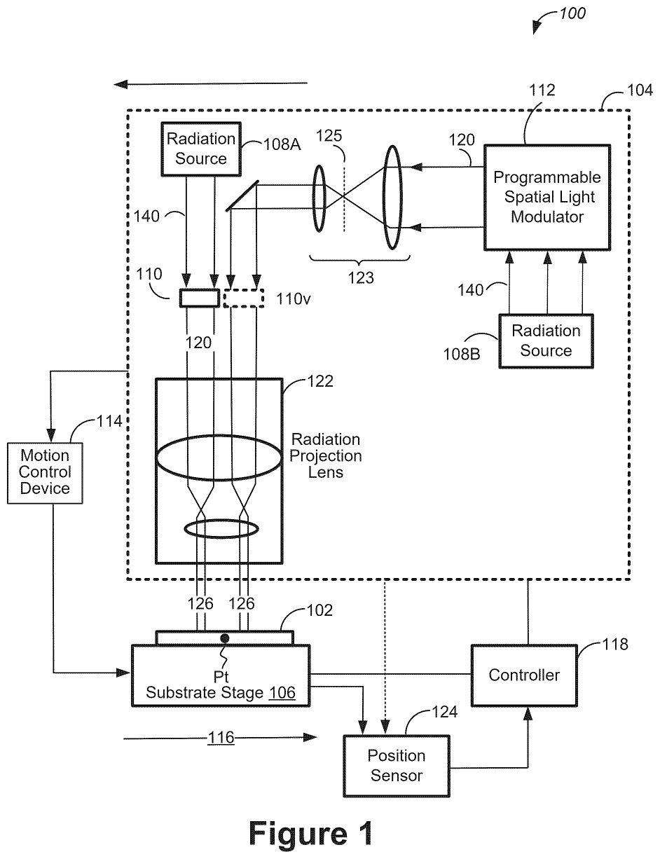

FIG. 1 is a schematic diagram showing an arrangement of a substrate processing system 100 (e.g., a lithographic stepper, or stereolithographic 3D printer) for implementing one or more scaled patterned exposures 126 on a substrate 102, in accordance with some embodiments. The substrate processing system 100 includes a radiation system 104 and a substrate support 106. The substrate stage 106 is configured to receive, support, and provide movement to, the substrate 102 that is disposed onto a top surface of the substrate stage 106. In some embodiments, the substrate 102 is mechanically fixed onto the top surface of the substrate stage 106, e.g., via air suction or an adhesive, and configured to move jointly with the substrate stage 106. The radiation system 104 is configured to provide a radiation source 108A that collaborates with a reticle 110 having a pattern to enable a patterned radiation 126 guided through a Radiation Projection Lens 122 towards the substrate 102, to produce a scaled patterned exposure 126 on the substrate 102. In some embodiments, the radiation source 108A includes a light source or an UV source, and has a patterned radiation 126 guided towards to the substrate 102. The reticle 110 is disposed on the radiation path of the light source at the object plane of the radiation projection lens 122, defining light of the light source to illuminate the substrate 102 through the Radiation Projection Lens 122 to produce the scaled patterned radiation exposure 126. Alternatively, in some embodiments, the radiation system 104 includes a radiation source 108B, a modulator 112 (e.g., an amplitude type PSRM, a phase type PSRM, or combination thereof), and a pattern relay with pre-scaler 123. The reticle 110 is not placed on the radiation path of the light source. Light of the light source is digitally modulated by the modulator 112 to adopt a spatial modulation pattern, scaled and relayed by the relay 123 to create a virtual reticle 110v at the object plane of the radiation projection lens 122, and illuminate the substrate 102 with the scaled modulated pattern 126.

In some embodiments, the substrate processing system 100 further includes a motion control device 114 (e.g. linear stage with a motor) coupled to at least one of the substrate stage 106 and the radiation system 104. The motion control device 114 is configured for the substrate stage 106, the radiation system 104, or both to move, thereby creating relative motion between a substrate 102 and a radiation system 104 in a predetermined direction 116. In addition, the motion control device 114 provides a relative motion between a substrate 102 and a radiation system 104 in one or two directions orthogonal to the predetermined direction 116. In some embodiments, the relative motion has a substantially constant velocity or a substantially constant acceleration during the exposure process. In some situations, the motion control device 114 creates the relative motion in the predetermined direction 116 by driving the substrate stage 106 carrying the substrate 102 to move in the predetermined direction 116 and driving the radiation system 104 to move in an opposite direction of the predetermined direction 116. Alternatively, in some situations, the substrate stage 106 and the substrate 102 are stationary, and the motion control device 114 drives the radiation system 104 to move in the opposite direction of the predetermined direction 116. Alternatively, in some situations, the radiation system 104 is stationary, and the motion control device 114 drives the substrate stage 106 carrying the substrate 102 to move in the predetermined direction 116.

In some embodiments, the substrate processing system 100 further includes a controller 118. The controller 118 determines that the substrate reaches a target position Pt of the substrate 102 at a target time and controls the radiation system 104 to enable a radiation operation 140, resulting in a patterned radiation exposure 126 on the substrate 106. The substrate 106 has a plurality of active areas that are aligned along a straight line substantially parallel to the predetermined direction 116. In accordance with a determination that the target position Pt of the substrate 102 matches a respective known position of a respective active area, the controller 118 enables the radiation operation (e.g., by generating a pulsed control signal to control the radiation source 108A or 108B to create illumination along the radiation path 140. Light of the radiation source 108A or 108B hits, and interacts with, the respective active area, In some embodiments, the radiation source 108A or 108B includes a light source generating in an infrared spectrum (750-3,000 nm), a visible light spectrum (e.g., 380-700 nm), an ultraviolet (UV) spectrum (e.g., 100-400 nm), an extreme ultraviolet (EUV) wavelength (e.g., about 13.5 nm), or an X-ray spectrum (0.01-10 nm). The active area of the substrate is covered with a photo sensitive layer or consists of a solid micro- and nano-particles suspended in a photosensitive solution and exposed by the light of the radiation source 108A or 108B. Alternatively, in some embodiments, the radiation source 108A or 108B is configured to generate electron beams, and the active area is processed by the electron beams generated by the radiation source 108A or 108B. In some embodiments, the radiation source 108A or 108B includes a laser configured to operate directly on the substrate 102 or directly on a structural layer formed on the active area of the substrate 102.

In some embodiments, the radiation system 104 includes a radiation projection lens system 122 configured to scale radiation 126 created by the radiation source 108A or 108B and modulated by reticle 110 or the PSRM 112 and guide radiation 126 towards the substrate 102. The radiation source 118 includes, or is coupled to, a beam homogenizer configured to smooth out irregularities in a radiation profile (e.g., a laser beam profile, a visible light profile, an electron beam profile) to create substantially uniform illumination 140. One potential embodiment of such beam homogenizer is described in the currently pending Ser. No. 18/403,344 filled by the applicant. In some embodiments, each active area exposed to the radiation operation has a compact area. In an example, the radiation projection lens system 122 makes features size on the reticle 110 and active areas match each other (e.g., have a ratio of 1:1). In another example, the radiation projection lens system 122 scales down a feature size on the reticle 110 or the PSRM 112 by a scale factor (e.g., 10×) to provide a smaller feature size of the active areas on the substrate 102. In some embodiments a pattern relay and pre-scaler 123 is used to scale down feature size created by the PSRM 112 by a scale factor (e.g., 25) and to relay patterned radiation 126 to the object plane of the radiation projection lens 122 to provide a scaled patterned exposure 126 on the substrate 102 with feature size of the active areas much smaller (e.g. 200×) than a physical size of individual elements (e.g. pixels, pistons, or mirrors) of the PSRM 112. In some embodiments a pattern relay and pre-scaler 123 incorporates a spatial filter located in a Fourier plane 125 and designed to pass certain selected diffraction orders, while attenuating all others. Design of such filters is well known to those skilled in the art.

In some embodiments, the substrate processing system 100 includes a position sensor 124 coupled to the substrate 102 or substrate stage 106 and the radiation system 104. The sensor 124 is configured to measure a position of the substrate 102 in relation to the radiation system 104 at a first sampling rate. The controller 118 obtains the position of the substrate 102 in relation to the radiation system 104 from the sensor 124 and determines a series of expected positions of the substrate 102 at a second sampling rate higher than the first sampling rate. The controller 118 further determines whether one of the series of expected positions is a target position associated with the active area of the substrate 102 and whether to enable the radiation operation 140 to be applied on the active area. Further, in some implementations, the substrate processing system 100 includes a lithographic stepper configured to trigger the radiation operation 140 at the right time to precisely synchronize scaled patterned radiation 126 with the predetermined location of the active area of the substrate 102. An example of the sensor 124 is a laser interferometer having the first sample rate of 20 MHz or below. Other examples of the sensor 124 include, but are not limited to, an encoder, an optical sensor, an inductive sensor, a capacitive sensor, and other types of sensors that are configured to measure a position of the substrate 102. In one of the examples a speed of the substrate 102 is 500 mm/s, and the substrate 102 moves a distance of 25 nm between two samples associated with the first sampling rate of 20 MHz. The required feature placement accuracy (e.g. 0.5 nm) of the features on substrate 102 is much smaller than the distance for which the substrate 102 moves between two samples of sensor 124 (25 nm) Additional positions are interpolated on the distance of 25 nm with a higher resolution, and the radiation operation 140 can be therefore controlled according to the higher resolution to comply with a requirement of the substrate 102. By these means, in some embodiments, high speed synchronization is achieved by measuring instantaneous velocity, velocity and acceleration, or velocity, acceleration and jerk of the substrate 102 in relation to the radiation system 104 and integrating a position of the substrate 102 in relation to the radiation system 104 from the first position to the target position.

In some situations, a position of the substrate 102 is fixed, and the motion control device 114 drives the radiation system 104 (e.g., radiation source 108A and reticle 110) to move in the opposite direction of the predetermined direction 116. This approach is especially advantageous if the size of the substrate 102 is greater than a certain threshold size on a dimension (e.g. exceed 300 mm in one or both dimensions). Such large substrates are commonly used in manufacturing of linear encoder devices and a flat screen devices. The radiation system 104 is driven to move to reduce the overall size and improve stability of the manufacturing equipment and facilitate manufacturing in such a large-size or high aspect-ration application. Conversely, in some situations, the radiation system 104 is fixed, and the motion control device 114 drives the substrate 102 to move in the predetermined direction 116 (e.g., continuously from a first position to a second position in the predetermined direction 116). In some situations, a traverse speed of the substrate 102 is substantially constant between the first position and the second position. Acceleration or deceleration happens when scaled radiation 126 is outside substrate bounds. The radiation operation 140 (e.g., exposure) is performed by pulsing the radiation source 108A or 108B. A plurality of active areas (also called dies) or repeated features are obtained by precisely synchronizing the radiation pulse with the position of the substrate 106. The radiation source 108A or 108B is configured to generate pulsed radiation 126. The pulsed radiation 126 has a substantially short pulse duration (e.g., picoseconds to not more than a few nanoseconds) to avoid image smearing (blur) caused by motion. The pulsed radiation 126 has a pulse energy configured to provide a target exposure dose for exposing the active area on the substrate 102.

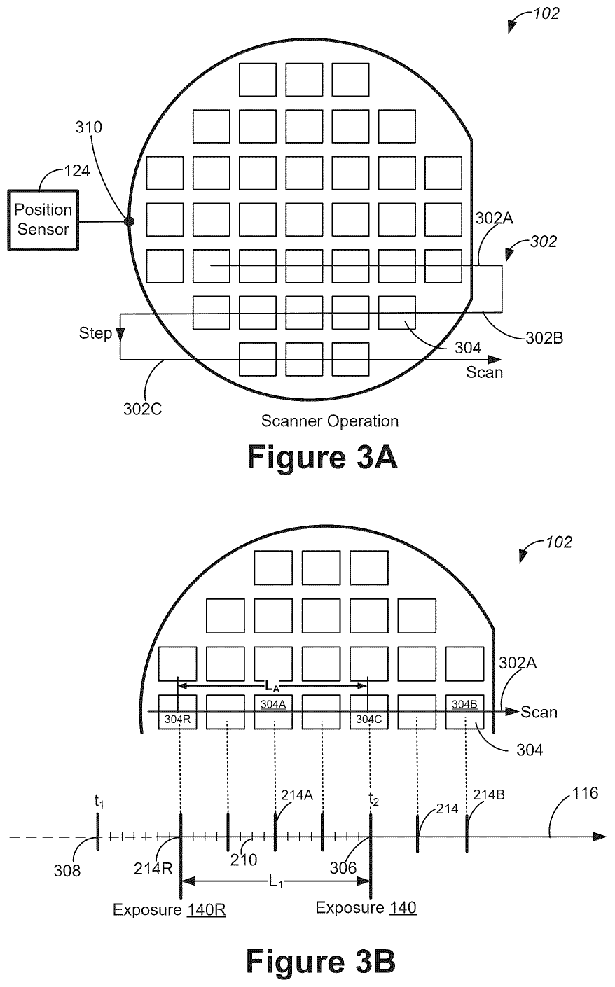

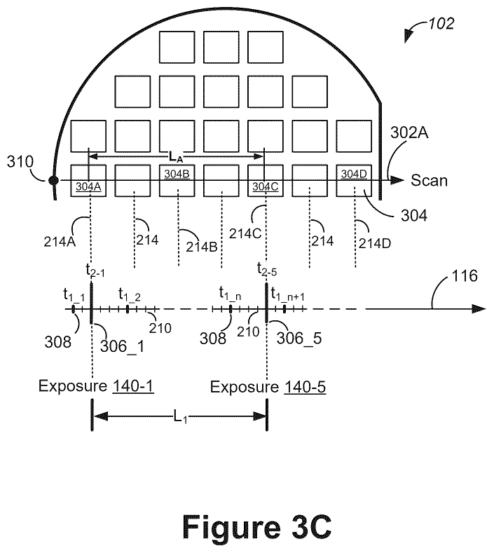

In some embodiments, a plurality of reticles 110 are applied in different radiation operations 140 on a plurality of sub-areas of an active area. In some embodiments, a reticle 110 includes a plurality of sub-patterns that are applied in different radiation operations 140 on sub-areas of an active area. Stated another way, the radiation system 104 applies different reticles 110, different sub-patterns of a reticle 110, or different programmable digital patterns of the PSRM 112 in association with a plurality of sub-areas of an active area of the substrate 102. The active area is included in a plurality of active areas, and corresponds to a die on the substrate 102. Each die has a unique pattern, a repeated pattern, or a combination of unique and repeated sub-patterns. Multiple dies can have empty space between them or be placed directly next to each other to produce a continuous pattern over the entire substrate. More details on forming different types of dies on the substrate 102 are discussed below with reference to FIGS. 3A-9.

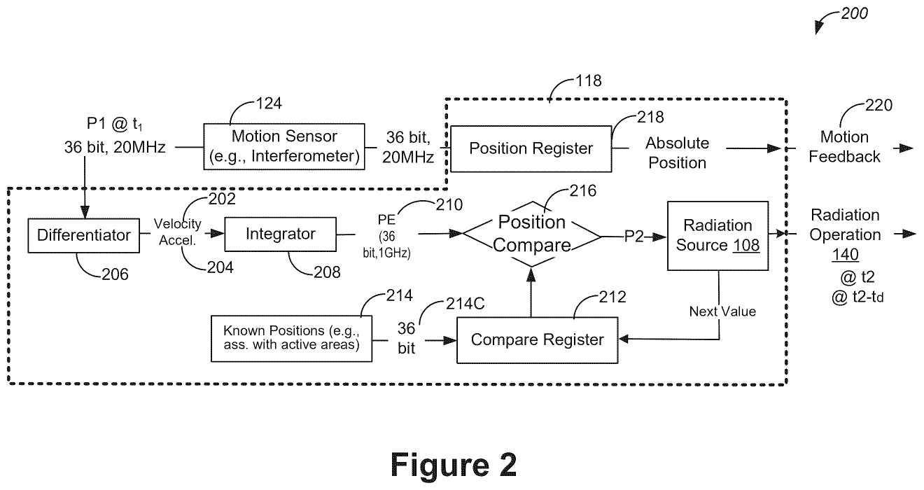

FIG. 2 is a block diagram of an example control system 200 for synchronizing substrate movement and a radiation operation 140, in accordance with some embodiments. A sensor 124 (e.g., a laser interferometer) is coupled to a radiation system 104 and a substrate stage 106 on which the substrate 102 is mounted. The sensor 124 is configured to measure a first position P1 of the substrate 102 at a first time t₁ at a first sampling rate f₁ (e.g., 20 MHz). A controller 118 is coupled to the sensor 124, and configured to obtain the position of the substrate 102 from the sensor 124 and determine a series of expected positions 210 (PE) of the substrate 102 at a second sampling rate f₂ (e.g., 1 GHz), which is higher than the first sampling rate f₁. The controller 118 is further configured to determine a second position P2 of the substrate 102 corresponding to t₂ later than the first time t₁ based on the series of expected positions 210. The substrate 102 is configured to be processed by the radiation operation 140 at the second time t₂. The radiation operation 140 is enabled at the second time t₂, which includes a predefined adjustment td associated with the signal and radiation propagation delays in controller 118 and the radiation system 104.

In some embodiments, the controller 118 determines a first speed 202 and a first acceleration 204 of relative motion between the substrate 102 and the radiation system 104 at the first time t₁. For example, the controller 118 includes a differentiator 206 that uses two positions of the substrate 102 to determine the first speed 202. The series of expected positions 210 are generated (e.g., by an integrator 208) based on the first position P1, the first speed 202, and the first acceleration 204 of the relative motion of the substrate 102.

In some embodiments, referring to FIG. 3C, the substrate 102 has a plurality of active areas 304 that are aligned along a straight line substantially parallel to the predetermined direction 116. The plurality of active areas corresponds to an ordered sequence of known positions 214 (e.g., 214A-214D) in the predetermined direction 116, and each of the known positions 214 is successively loaded into a register 212. After the first time t₁, the series of expected positions 210 is successively compared (operation 216) with a current known position 214C loaded in the register 212. For each of a subset of expected position 210, the controller determines whether the respective expected position 210 matches the current known position 214C loaded in the register 212. In accordance with a determination that the respective expected position 210 matches the current known position 214C, the controller 118 identifies the respective expected position 210 as the second position P2, and identifies the second time t₂ that is later than the first time t₁ and corresponds to the second position P2. The controller 118 further controls a radiation source 108A or 108B to enable the radiation operation 140 that is applied on the respective active area, corresponding to the current known position 214C of the substrate 102, at the second time t₂.

Stated another way, in some embodiments, the plurality of active areas (e.g., 302 in FIG. 3A) correspond to a plurality of trigger events for which radiation operations 140 are enabled. Locations of the active areas on the substrate 102 are converted to known positions 214 of the substrate 102 on the predefined direction 116, and the known positions 214 are loaded into the compare register 212 successively. Upon detection of a known position 214 in the expected positions 210, the radiation operation 140 is triggered at the second time t₂, and a next known position 214 is loaded to the register 212. After the second time t₂, remaining expected positions 210 in the ordered sequence of expected positions 210 are continued to be compared (operation 216) with the next known position to detect a next active area associated with a next trigger event. The comparison operation 216 is synchronized to the second sampling frequency f₂ (e.g., 1 GHz internal clock), which allows the controller system 200 to update the expected position 210 accordingly (e.g., every 1 ns). In some embodiments, the relative motion between the substrate 102 and the radiation system 104 has a substantially constant velocity during an exposure pass. The controller 118 (e.g., an FPGA) performs a highly accurate integration over each sampling period (e.g. 50 ns) between two samples from the sensor 124. This integration improves the position resolution by a factor (e.g., 50 times). In an example, the substrate stage 106 has a velocity of 500 mm/s, and 1 ns uncertainty translates to a worst-case position synchronization error of 0.5 nm, which can be further enhanced using a higher performance controller 118 (e.g., FPGA or ASIC with an internal clock higher than 1 GHz).

In some embodiments, a position of the substrate 102 measured by the sensor (e.g., at the first sampling rate f₁) is also applied to control motion of at least one of the substrate 102 and the radiation system 104. A position register 218 is used to provide a position of the substrate 102 in relation to the radiation system 104 at a predetermined update rate (e.g. 20 kHz) for use as a motion feedback signal 220 to be used by a motion controller. Motion controller processes the position data at a much lower rate (e. g 20 kHz) rate and updates a drive current to a motor to maintain a target acceleration, velocity, and position. A motor is controlled to move at least one of the substrate 102 and the radiation system 104 based on the motion feedback signal 220.

Some implementations of this application relies on position detection to control the radiation operation 140, and a target position of the substrate 102 corresponding to a trigger event is monitored and identified before the radiation operation 140 is initiated. In real life systems small fluctuations (jitter) always occur to the velocity within a motor control interval (e.g., a 50 μs interval, which corresponding to 20 kHz motion controller cycle) due to random perturbations in motor drive current, linear guide friction variations, air flow, drag, and/or temperature gradients. The motor updates its motor drive current once during each motor control interval, and does not react to fluctuation within the respective motor control interval. The controller 118 takes advantage of a higher sampling rate (20 MHz) available from sensor 124 and includes a differentiation circuit configured to measure and compensate for high frequency velocity jitter (e.g., within each 50 μs interval) by differentiating two or more consecutive positions and obtaining actual measured velocity and acceleration at the first sampling rate f₁ (e.g., 20 MHz), which is faster than the motion control interval (e.g., by 1000 times).

In some embodiments, a measured acceleration is used to enhance an interpolated position accuracy of the series of expected positions 210. For example, Pᵢ represents a current position measured for the substrate 102. Pᵢ₋₁ and Pᵢ₋₂ represent positions measured at two previous sampling intervals, where each sampling interval has a temporal length (e.g., 50 ns) that corresponds to the first sampling rate f₁ (e.g., 20 MHz). The positions Pᵢ, Pᵢ₋₁, and Pᵢ₋₂ are measured by the sensor 124, which is one of an interferometer, an encoder, or any other position sensor capable of high speed and high resolution motion measurement over a long distance (e.g., greater than 300 mm). In an example, a current velocity Vᵢ is determined as (Pᵢ−Pᵢ₋₁)/Δt or (3Pᵢ−4Pᵢ₋₁+Pᵢ₋₂)/(2Δt), and a current acceleration aᵢ is determined as (Pi−2Pi-1+Pi-2)/Δt². An interval dT is an upsampled Δt. For example, Δt is 50 ns, and dT is 1 nm. After a number (n) of upsampled intervals dT have passed, an upsampled position Pu is represented as Pᵢ+nVᵢdT+1/2aᵢn²dT², and compared to a known position 214C (e.g., a target position for radiation operation) at upsampled intervals (e.g., at 200 MHz). In some embodiments, the known position 214C (e.g., also seen in FIG. 3C) is determined based on an actual physical position of a respective active area on the substrate 102, and adjusted to degradation factors (e.g., compensate signal propagation delays, processing time). In some embodiments, the controller 118 applies a pipeline architecture to determine the expected positions 210 interpolated from the measured positions. A new value enters a pipeline at the second sampling rate f₂(e.g., every 1 ns), so does a result exit the pipeline. The exiting result corresponds to a position which was current several cycles ago. This is the number of cycles the controller 118 requires to generate the result. The known or target position 214C to which the result is compared is adjusted accordingly.

Additionally, in some embodiments, the controller 118 determines the expected positions 210 based on a third derivative of the position of substrate 102, which is associated with a jerk or the rate of change in acceleration, in addition to the first derivative (e.g., a velocity) and the second derivative (e.g., an acceleration). The jerk associated with the position of the substrate 102 is determined based on a current position Pᵢ and positions Pᵢ₋₁, Pᵢ₋₂, and Pᵢ₋₃ measured at three previous sampling intervals. An instantaneous velocity, acceleration, and jerk is determined at the first sampling rate fᵢ and integrated at the second sampling frequency f₂ to enhance the accuracy level of expected positions 210 interpolated based on the positions of the substrate 102 measured by the sensor 124 at the first sampling rate f₁.

FIG. 3A is a top view of an example where substrate 102 moves with reference to a radiation system 104, in accordance with some embodiments, and FIGS. 3B and 3C are top views of a portion of an example substrate 102 configured to be processed by a series of radiation operations 140, in accordance with some embodiments. The substrate 102 is fixed on, and moves jointly with, a substrate stage 106 (FIG. 1) mechanically driven by a motion control device 114 (e.g., a motor). A radiation system 104 is configured to provide a scaled patterned radiation 126 on a radiation area of a top surface of the substrate 102. The radiation system 104 is moved to select an area to be exposed to the radiation 126. Relative motion is created between the substrate 102 and the radiation system 104, allowing the substrate 102 to move in a predetermined direction 116 with respect to the radiation system 104. In some embodiments, the radiation area associated with the radiation system 104 moves on the top surface of the substrate 102 according to a predefined path 302 including a first straight line 302A, a second straight line 302B, and a third straight line 302C. The predefined path 302 changes its path direction when the predefined path 302 switches from the first straight line 302A to the second straight line 302B and from the second straight line 302B to the third straight line 302C. Each of the straight lines 302A-302C is substantially parallel to a respective predetermined direction 116 of the substrate 102.

For each of the straight lines 302A-302C, the radiation system 104 scans a respective set of active areas 304 arranged in the predetermined direction 116 of the substrate 102. A radiation operation 140 is enabled, in accordance with a determination that the radiation area associated with the scaled patterned radiation 126 overlaps, and is substantially aligned with, each active area 304 for a predetermined duration of time. Each active area 304 corresponds to a known position 214 of the substrate 106 in its predetermined direction 116. The controller 118 detects alignment of the scaled patterned radiation 126 with each active area 304 in accordance with a determination that the substrate 106 reaches a known position 214.

Referring to FIG. 3B, in some embodiments, the active areas 304 includes a reference active area 304R. The controller 118 identifies a reference position 214R of the substrate 102 corresponding to the reference active area 304R. The reference position 214R is determined based on a series of expected positions 210 of the substrate 102 at a second sampling rate f₂. When the substrate 102 reaches the reference position 214R, the radiation operation 140R is enabled and applied on the reference active area 304R. A second position 306 is identified with reference to the reference position 214R. In accordance with a determination that the second position 306 matches one of the plurality of known positions 214, a first distance L₁ of the second position 306 and the reference position 214R matches a second distance L_{A} of the respective active area 304C corresponding to the second position 306 and the reference active area 304R. In some embodiments, the controller 118 tests each of the series of expected positions 210 until the second position 306 is identified based on the first distance L₁. Alternatively, in some embodiments, the first position 308 is refreshed and located between the reference position 214R and the second position 306.

In some embodiments, a speed of the substrate 102 is determined based on a first position 308 of the substrate 102. The substrate 102 passes the first position 308 before the second position 306. The controller 118 identifies the reference position 214R of the substrate 102 corresponding to the reference active area 304R. The second position 306 is identified with reference to the reference position 214R based on the speed of the substrate 302. Further, in some embodiments, the controller 118 determines a distance L₁ between the second position 306 and the reference position 214R based on a product of the speed 202 of the substrate 102 and a temporal length between the positions 214R and 306. The temporal length is a product of a number of expected positions 210 generated between the reference position 214R and the second position 306 and a sample period T_{S} corresponding to the second sampling rate f₂. The second position 306 is located at the predetermined direction 116 of, and has the distance L₁ from, the reference position 214R.

Referring to FIG. 3C, in some embodiments, a first time t_{1_1} happens outside of the active area 304A, and a first position is measured at the first time t_{1_1}. Additional positions are measured at times t_{1_2}, . . . , t_{1_n}, t_{1_n+1} corresponding to a pace of 25 nm (e.g., which is associated with a relatively low position sensing frequency). Positions 210 are interpolated at a higher sampling rate between every two successive times of t_{1_2}, . . . , t_{1_n}, t₁₋ₙ₊₁. The expected positions 214 (e.g., 214A, 214B, 214C, and 214D) are compared to the interpolated positions to detect second positions 306_1, 306_2, etc at second times t_{2_1}, t_{2_2}, etc.

In some embodiments, in response to detection of the second position 306 of the substrate 102 at a second time t₂, a radiation operation 140 is implemented by controlling a radiation source (e.g., coupled to a reticle 110 or coupled to a PSRM 112) by a radiation control signal to generate a scaled patterned radiation 126 (FIG. 1) that exposes a corresponding active area 304C of the substrate 102 for a predetermined duration of time. The predetermined duration of time is a predefined temporal length. The radiation operation 140 is controlled to power on and off with different power levels, and a beam direction is fixed for each radiation source (e.g., coupled to a reticle 110 or couple to a PSRM 112). In an example, the radiation operation 140 includes a photolithographic exposure. In another example, the radiation operation 140 includes a patterned polymerization of a media in which solid micro- or nano-particles are suspended. Patterning operation is repeated at different heights and the substrate is subsequently cured at high temperature to fuse the patterned particles together and to additively manufacture three-dimensional solid parts. In yet another example, the radiation operation 140 includes an electron beam write operation. In some embodiments, the radiation source provides substantially uniform illumination to expose the corresponding active area 304 or a subarea 504 thereof during the predetermined duration of time.

The relative motion associated with the substrate 102 is maintained between the substrate 102 and the radiation system 104 during the radiation operation 140. In some embodiments, a position accuracy level and an edge roughness level of a feature produced on the substrate by the radiation operation 140 is defined based on a temporal length of the predetermined duration of time and a speed of the substrate 102.

In some embodiments, the radiation source 108A is coupled to the reticle 110 configured to modulate the substantially uniform illumination 140 according to a pattern of the reticle 110, thereby forming a pattern of radiation exposure on the corresponding active area 304 during the predetermined duration of time. Alternatively, in some embodiments, a PSRM 112 (FIG. 1) provides respective patterned radiation exposure on the corresponding active area 304 during the predetermined duration of time. The radiation operation 140 is implemented at the PSRM 112, which spatially modulates radiation to provide the respective patterned radiation exposure.

In some embodiments, the substrate 102 corresponds to a semiconductor wafer (e.g. having a diameter of 300 mm or less). In some embodiments, the substrate 102 has a high aspect ratio corresponding to an extended length. For example, a length of the substrate 102 is greater than 300 mm, e.g., equal to 3,200 mm. The relative motion of the substrate 102 is made the radiation operations 140 available to expose the plurality of active areas 304 located on the entire length of the substrate 102. In some situations, the relative motion of the substrate 102 has a substantially constant velocity along the predetermined direction 116 without interruptions associated with movement between active areas. By these means, the substrate processing system 100 avoids significant vibrations or additional complex solutions to mitigate the effects of vibration caused by start/stop acceleration while moving between active areas (or dies).

In some embodiments, a set of active areas 304 (e.g., 7 active areas 304 on FIG. 3B) are arranged on the first straight line 302A. The substrate 102 has a plurality of known positions 214 (FIG. 2) each of which corresponds to a respective active area 304. When the substrate reaches each known position 214, the respective active area 304 is aligned with a fixed location of a radiation system 104, and is configured to be exposed to radiation 126 (FIG. 1) generated by the radiation system 104.

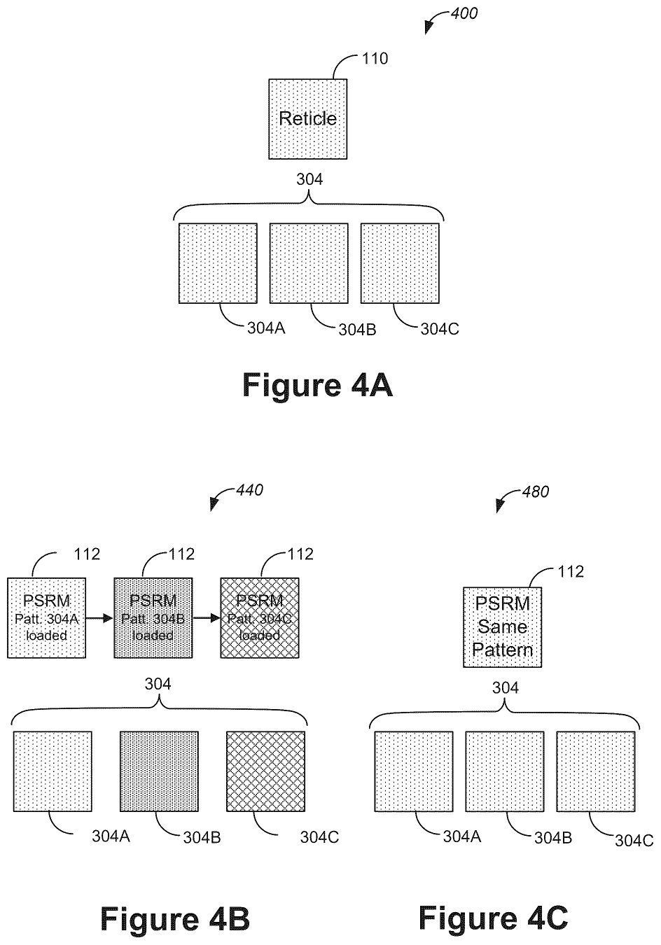

In some embodiments, the plurality of known positions 214 includes a first known position 214A and a second known position 214B. In accordance with a determination that the second position 306 matches the first known position 214A, the controller 118 controls a first radiation source (e.g., a radiation source coupled to the PSRM 112 in FIG. 1) to provide a first pattern of radiation exposure on a first active area 304A of the substrate 102. In accordance with a determination that the second position 306 matches the second known position 214B, the controller controls the first radiation source (e.g., a radiation source coupled to the PSRM 112 in FIG. 1) to provide a second pattern of radiation exposure on a second active area 304B of the substrate 102. The first pattern formed on the first active area 304A is distinct form the second pattern formed on the second active area 304B. More details on forming a set of different active areas are discussed below with reference to FIG. 4B.

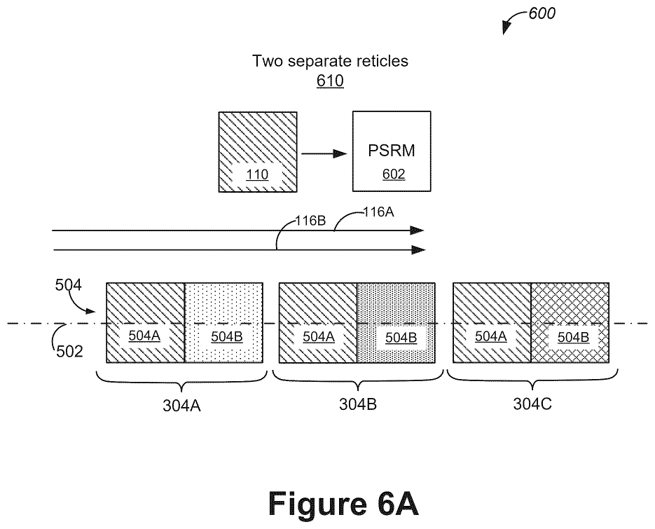

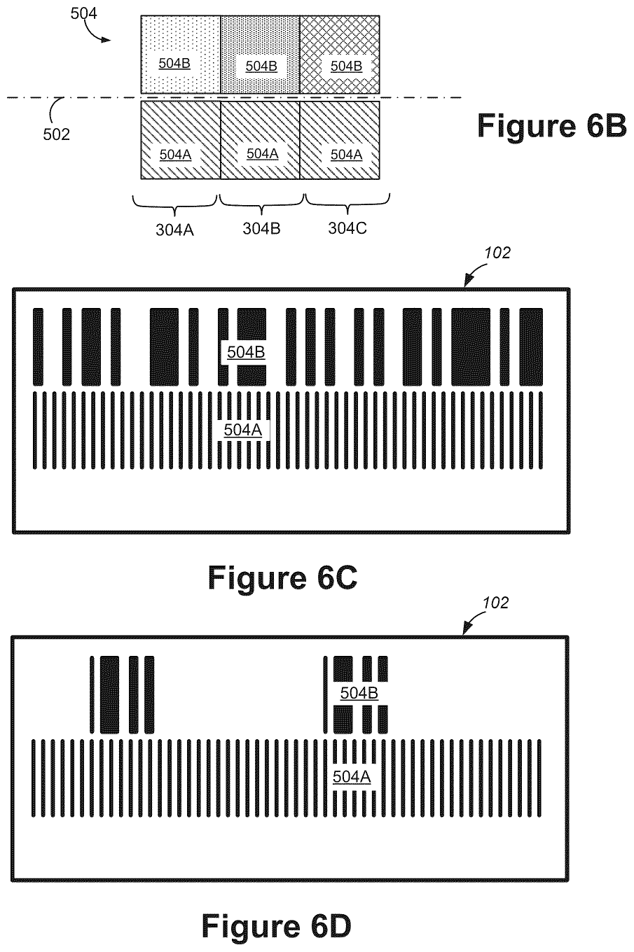

In some embodiments, in accordance with a determination that the second position 306 matches the first known position 214A, the controller (1) controls a first radiation source (e.g., radiation source 108A or 108B) by a first radiation control signal to provide a fixed pattern of radiation exposure on a first subarea of a first active area 304A of the substrate 102 and (2) controls a second radiation source (e.g., coupled to a PSRM 112) by the second radiation control signal to provide a first pattern of radiation exposure on a second subarea of the first active area 304A of the substrate 102. Further, in some embodiments, the plurality of known positions 214 further includes a second known position 214B. In accordance with a determination that the second position 306 matches the second known position 214B, the controller 118 (1) controls the first radiation source by the first radiation control signal to provide the fixed pattern of radiation exposure on a first subarea of a second active area of the substrate 102, and (2) controls the second radiation source by the second radiation control signal to provide a second pattern of radiation exposure on a second subarea of the second active area of the substrate 102. The first pattern is distinct form the second pattern. In some situations, the first radiation source (e.g., coupled to a PSRM 112) and the second radiation source (e.g., coupled to a reticle 110) is controlled concurrently. In some situations, the first radiation source (e.g., coupled to a PSRM 112) and the second radiation source (e.g., coupled to a reticle 110) is controlled sequentially in two radiation scans. More details on forming a set of different subareas are discussed below with reference to FIG. 6A.

FIGS. 4A-4C are three diagrams 400, 440, and 480 illustrating three sets of neighboring active areas 304 (e.g., 304A, 304B, and 304C) and associated optical arrangements, in accordance with some embodiments. Referring to FIG. 4A, in some embodiments, the reticle 110 is applied to define a pattern on a plurality of active areas 304A, 304B, and 304C successively. The reticle 110 is not changed when the substrate 102 has relative motion with respect to the radiation system 104 along the first direction 116. The same pattern is defined on the active areas 304A, 304B, and 304C.

Referring to FIGS. 4B and 4C, in some embodiments, a PSRM 112 is applied in place of the reticle 110, and configured to provide an adaptive pattern to define a distinct pattern on each of the active areas 304A, 304B, and 304C. In some embodiments (FIG. 4C), a fixed pattern is loaded by the PSRM 112, and applied in three successive radiation operations 140. The same pattern is defined on the active areas 304A, 304B, and 304C. Alternatively, in some embodiments (FIG. 4B), distinct patterns are loaded by the PSRM 112, and applied in successive radiation operations 140. In this example three different patterns are defined on the active areas 304A, 304B, and 304C, respectively. More details on forming a set of different active areas are discussed above with reference to FIGS. 3A-3C.

In some embodiments, the PSRM 112 includes a programmable spatial light modulator of an amplitude type, a programmable spatial light modulator of a phase type, or programmable spatial light modulators of both types. In some of the embodiments a digital micromirror device (DMD) serves as one or more of the programmable spatial light modulators. The DMD type, has an array of micromirrors that are configured to be driven by real-time image data to form an adaptive two-dimensional pattern of varying amplitude or phase. Different image data are loaded by the PSRM 112 in real-time for each radiation operation 140 to drive the PSRM without interrupting the relative motion of the substrate 102 and the radiation system 104.

Stated another way, an active area is defined by a pattern by different methods. In some embodiments, an amplitude modulator (e.g. a digitally modulated micromirror device with tilting mirrors) is applied. In some embodiments, a phase type modulator is applied, and includes mirrors that are digitally controlled in a piston-like motion. In some embodiments mirrors are modulated by an analog signal. In some embodiment, electromagnetic coils are used to modulate the e-beam radiation. In some embodiments, both amplitude and phase modulations are applied. It is noted that, in some embodiments, a spatially-modulated radiation exposure is enabled to form a two-dimensional geometric pattern on an active area of a substrate.

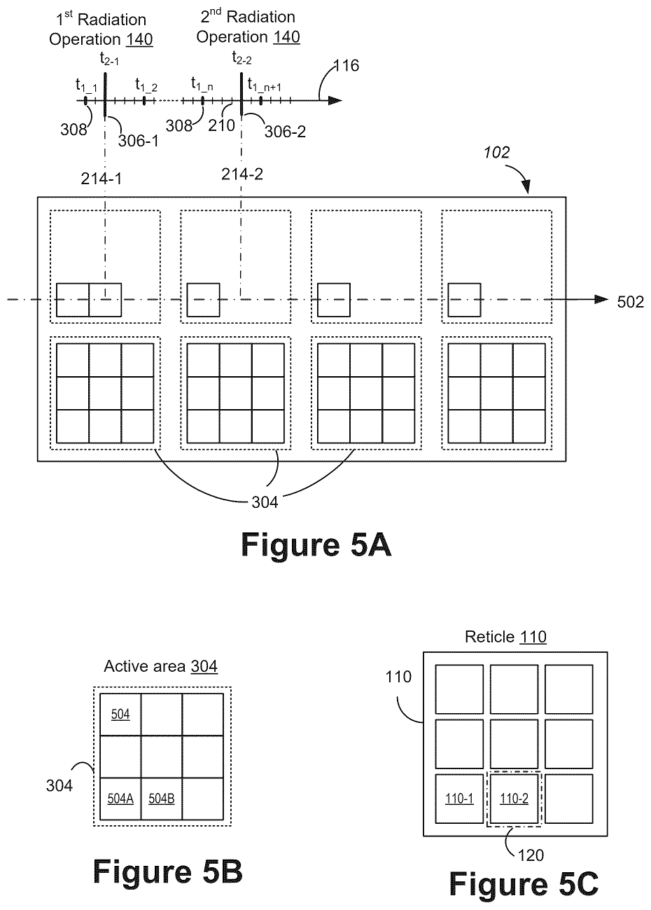

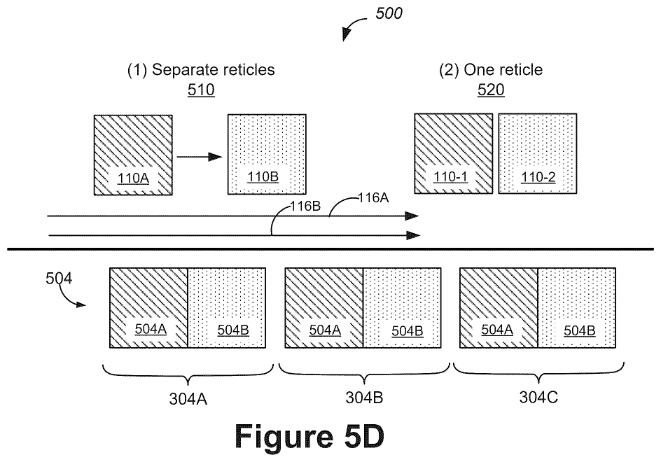

FIG. 5A is a top view of a substrate 102 having at a plurality of structured active areas 304 each of which further includes a plurality of subareas 504, in accordance with some embodiments. FIG. 5B shows an example of an active area 304 being composed of nine subareas 504. FIG. 5C is an example of a reticle which can be used to produce active area 304 shown in FIG. 5B in accordance with arrangement 520. FIG. 5D is a diagram 500 illustrating a set of identical neighboring active areas 304 and two associated reticle arrangements 510 and 520, in accordance with some embodiments. The substrate 102 has a plurality of active areas 304, e.g., two rows and four columns of active areas 304. The substrate 102 is fixed on, and moves jointly with, a substrate stage 106 (FIG. 1) mechanically driven by a motion control device 114 (e.g., a motor). A radiation system 104, the substrate 102, or both are moved to select an active area 304 and subarea 504 to be exposed to scaled patterned radiation 126. In some embodiments, the radiation system 104, substrate 102, or both are moved to select a sequence of active areas 304 to be exposed successively to radiations 126 associated with a plurality of radiation operations 140. Each active area 304 includes a plurality of subareas 504. For each radiation operation 140, only a subset of the plurality of subareas 504 of a respective active area 304 is exposed to radiation 126.

Referring to FIG. 5A, in some embodiments, a set of active areas 304 are aligned along a straight line 502 substantially parallel to a predetermined direction 116 of relative motion of the substrate 102. Each active area 304 includes a plurality of subareas: first subarea 504A, second subarea 504B, etc. In the example on FIG. 5A, all subareas 504A have been already exposed. At the second position 306-1 of the substrate 102 radiation system 104 was aligned with the known location 214-1 of the subarea 504B in the first column of the second row of active areas and was exposed to the first radiation operation at t₂₋₁. Second position 306-1 was identified among the series of expected positions 210 which were calculated at second sampling rate f₂ (e.g., 1 GHz) based on the immediately preceding first position 308 measured at t₁₋₂ by sensor 124 at the first sampling rate f₁ (e.g., 20 MHz). At the second position 306-2 of the substrate 102 radiation system 104 is aligned with the known location 214-2 of the subarea 504B in the second column of the second row of active areas. Second position 306-2 is identified at t₂₋₂ among the series of expected positions 210 which are calculated at second sampling rate f₂ (e.g., 1 GHz) based on the immediately preceding first position 308 measured at t_{1_n} by sensor 124 at the first sampling rate f₁ (e.g., 20 MHz). Position 306-2 is exposed to a radiation operation 140 at the second time t₂₋₂ Specifically, a subarea 504B, located in the second column of the second row of the plurality of active areas 304 is exposed to the radiation operation 140.

Referring to FIG. 5D, in some embodiments, while the substrate 102 moves along a first direction 116A, a radiation source (e.g., coupled to a reticle 110 or coupled to a PSRM 112) is controlled to provide radiation exposure successively on the first subarea 504A of each active area 304A, 304B, 304C of the substrate 102. While the substrate 102 moves along a second direction 116B, is controlled to provide radiation exposure successively on the second subarea 504B of each active area 304A, 304B, 304C of the substrate 102. In some embodiments, a line connecting centers of the first subarea 504A and the second subarea 504B is parallel to the first direction 116A, and the first direction 116A and the second direction 116B are colinear. In some embodiments, a line connecting centers of the first subarea 504A and the second subarea 504B has a shift perpendicular to the first direction 116A, and the second direction 116B has the shift with respect to the first direction 116A while keeping parallel to the first direction 116A.

The first subareas 504A of the active areas 304A, 304B, and 304C are defined by the same reticle 110 and identical to each other, so are second subareas 504B of the active areas 304A, 304B, and 304C. The first subareas 504A has a different pattern from the second subareas 504B. Referring to FIG. 5D, in some embodiments associated with a reticle arrangement 510, two distinct reticles 110A and 110B are applied with two radiation scans associated with the first direction 116A and the second direction 116B, respectively. A second reticle 110A is disposed in a radiation path 120 (FIG. 1) in place of a first reticle 110A between the two radiation scans. Alternatively, in some embodiment not shown, the PSRM 112 applies two distinct patterns for the two radiation scans associated with the first direction 116A and the second direction 116B, respectively. Alternatively, in some embodiments, associated with a reticle arrangement 520, two distinct portions of a reticle 110 are applied with two radiation scans associated with the first direction 116A and the second direction 116B, respectively. In some embodiments a single reticle 110 contains patterns for two or more distinct subareas, e.g. pattern 110-1 and 110-2. The reticle 110 is then mechanically shifted to load a second portion 110-2 onto the radiation path 120 (FIGS. 1, 5C) in place of a first portion 110-1 between the two radiation scans. In some embodiments not shown, the first subarea 504A and the second subarea 504B partially overlap with one another in a way that every region of each active area is exposed to the scaled patterned radiation 126 of the radiation source 108A or 108B at least twice, and each overlapping exposure is performed with a unique pattern.

FIG. 6A is a diagram 600 illustrating a set of distinct neighboring active areas 304 and an associated optical arrangement 610, in accordance with some embodiments, and FIG. 6B is a top view of an example substrate 102 having a plurality of active areas 304 distributed along an extended length of the substrate 102, in accordance with some embodiments. The substrate 102 has a plurality of active areas 304 (e.g., 304A, 304B, and 304C) arranged along a straight line that is parallel to a predetermined direction 116 of motion of the substrate 102. The substrate 102 is fixed on, and moves jointly with, a substrate stage 106 (FIG. 1) mechanically driven by a motion control device 114 (e.g., a motor). A radiation system 104, the substrate 102, or both are moved to select an active area 304 to be exposed to radiation 126. Each active area 304 includes a plurality of subareas 504. For each radiation operation 140, one of the plurality of subareas 504 of a respective active area 304 is exposed to radiation 126. While the substrate 102 moves along a first direction 116A, a radiation source (e.g., coupled to a reticle 110) is controlled to provide radiation exposure successively on the first subarea 504A of each active area 304A, 304B, 304C of the substrate 102. While the substrate 102 moves along a second direction 116B, a radiation source (e.g., coupled to a PSRM 112) is controlled to provide radiation exposure successively on the second subarea 504B of each active area 304A, 304B, 304C of the substrate 102.

The optical arrangement 610 includes a combination of a first reticle 110 and a programmable reticle 602 provided by the PSRM 112 (FIG. 1), thereby allowing for placement of repeated patterns and unique patterns on first subareas 504A and second subareas 504B of a plurality of active areas 304, respectively. The first subareas 504A and the second subareas 504B are arranged in an interleaving manner (FIG. 6A) or in a stacked manner (FIG. 6B) in the plurality of active areas 304. Plurality of other arrangement and combinations are possible (not shown), including arbitrary number of stacked rows and columns, arbitrary number of unique and repeated patterns, overlapping patterns, etc. In some embodiments, the unique patterns formed on the second subareas 504B correspond to serial numbers and other identifiers.

FIGS. 6C and 6D are diagrams illustrating two example optical encoder grating substrates 102, in accordance with some embodiments. Absolute optical encoder gratings are created on the substrate 102. The repeated patterns formed on the first subareas 504A make up for an incremental encoder track, while the unique patterns formed on the second subareas 504B make up an absolute position encoding track. Stated another way, the second subareas 504B form a pseudorandom absolute code. In an alternative embodiment shown on FIG. 6D, the second subareas 504B form periodic or distance codded reference marks.

Referring to FIGS. 5A through 6D, in some embodiments, the first subarea 504A and the second subarea 504B of each active area 304 partially overlap each other in a way that every region of each active area is exposed to scaled patterned radiation 126 at least twice, and each overlapping exposure is performed with its own unique pattern. Overlap is achieved by introducing an offset between subareas 504 in the predetermined direction 116 and/or in a direction orthogonal to the predetermined direction 116. Offset is uniquely selected for each pass based on the number of exposures and equals to a fraction (e.g. ½, ⅓, ¼, ¾, etc.) of an active area 304 in the direction of the offset. In some embodiments, the first subarea 504A and the second subarea 504B of each active area 304 are connected to each other without any gap. In some embodiments, the first subarea 504A and the second subarea 504B of each active area 304 are immediately adjacent to each other, and separated by a gap (e.g., having a width of 20 μm). Each subarea 504A or 504B is exposed by a respective scaled and patterned radiation 126 provided by a respective radiation source, and the respective scaled and patterned radiation 126 is triggered at a precise time synchronized to an expected position 214 of the substrate 102 associated with the subarea 504A or 504B.

Referring to FIG. 6B, two first subareas 504A of two neighboring active areas 304 overlap each other, be connected to each other without any gap, or be separated each other by a gap (e.g., having a width of 20 μm). Independently of the first subareas 504A, two second subareas 504B of two neighboring active areas 304 overlap each other, be connected to each other without any gap, or be separated each other by a gap (e.g., having a width of 20 μm). Moreover, subareas 504B and neighboring subareas 504A overlap each other, be connected to each other without any gap, or be separated each other by a gap (e.g., having a width of 100 μm) More details on forming a set of different subareas 504A and 504B are discussed above with reference to FIGS. 3A-3C.

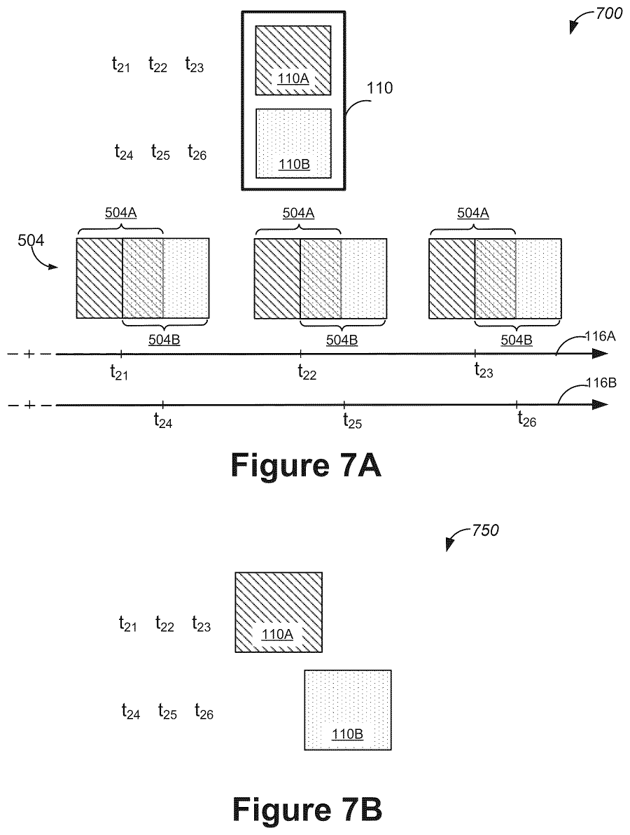

FIGS. 7A and 7B are diagrams 700 and 750 illustrating a set of identical neighboring active areas 304 and two associated split mask arrangements, in accordance with some embodiments, respectively. A repeated pattern is broken into multiple smaller sub-patterns, and sub-patterns are placed on the same reticle. In some embodiments, one sub-pattern is exposed over entire wafer, and reticle is shifted to the next sub-pattern which is then also exposed over entire wafer. In some embodiments, one or more overlapping exposures can be performed to ensure defect-free stitching of the sub-pattern boundaries. For active areas 304 using sub-patterns, exposure field is smaller, allowing application of smaller and cheaper radiation projection lens and lower power radiation sources.

A substrate 102 includes a plurality of identical active areas 304, and each active areas 304 includes a plurality of subareas 504, e.g., a first subarea 504A and a second subarea 504B. In some embodiments, the radiation system 104 is fixed, and the substrate 102 moves along a first direction 116A to enable a series of radiation operations 140 that exposes the firs subareas 504A of the active areas 304A, 304B, and 304C at three successive times t₂₁, t₂₂, and t₂₃. Each time t₂₁, t₂₂, or t₂₃ corresponds to a respective one of a plurality of expected positions 210 that are determined on the first direction 116A. The expected positions 210 corresponding to the times t₂₁, t₂₂, and t₂₃ are separated by distances corresponding to distances among the first subareas 504A of the active areas 304A, 304B, and 304C. Further, the substrate 102 moves along a second direction 116B to enable another series of radiation operations 140 that exposes the second subareas 504B of the active areas 304A, 304B, and 304C at three successive times t₂₄, t₂₅, and t₂₆, which are subsequent to the times t₂₁, t₂₂, and t₂₃. Each time t₂₄, t₂₅, or t₂₅ corresponds to a respective one of a plurality of expected positions 210 that are determined on the second direction 116B. The expected positions 210 corresponding to the times t₂₄, t₂₅, and t₂₆ are separated by distances corresponding to distances among the second subareas 504B of the active areas 304A, 304B, and 304C. In some embodiments a PSRM is used to create varying active areas. Referring to example on FIG. 7A, patterns 110A and 110B corresponding to the subareas 504A and 504B can be uploaded to the PSRM in real-time and exposed during a single movement, with radiation operations triggered in the following sequence: t₂₁, t₂₄, t₂₂, t₂₅, t₂₃, t₂₆. The next pattern is uploaded into the PSRM between the radiation operations while the substrate 102 is in motion, e.g. before t₂₁, then during the interval t₂₁-t₂₄, then during the interval t₂₄-t₂₂, etc. More details on determination of the times t₂₁-t₂₆ are discussed above with reference to FIGS. 3A-3C.

In some embodiments, the second direction 116B is parallel to and points in the same direction as the first direction 116A. After the last active area 304 close to an end of a row has been exposed, the motion is reversed and the substrate is returned to a start, and stepped in the orthogonal direction, if necessary, to align with the second direction 116B, parallel or collinear to the first direction 116A, to expose the second subareas 504B successively. Conversely, in some embodiments, the second direction 116B is opposite to the first direction 116A. After the last active area 304 close to an end of a row has been exposed, the substrate 102 is not moved to a start, and instead, moves back along the second direction 116B that is opposite to the first direction 116A to expose the second subareas 504B at the times t₂₆, t₂₅, and t₂₄ successively.

At least two distinct reticles 110A and 110B are applied to create radiation operations 140 when the substrate 102 moves on the first direction 116A and second direction 116B, respectively. Referring to an example in FIG. 7A, in some embodiments, the two distinct reticles 110A and 110B have the same locations, and aligned with the same radiation projection lens 122 (FIG. 1) or the same portion of the radiation projection lens 122. The known positions 214 of the subareas 504 of the active areas 304A are calculated for the radiation operations 140 corresponding to the first direction 116A and second direction 116B separately based on the known distance and overlap between subareas 504. Referring to FIG. 7B, in some embodiments, the two distinct reticles 110A and 110B have different locations, aligned with a different portion of the same radiation projection lens 122 (FIG. 1) or have their own independent radiation projection lens 122. A known offset between reticles is taken into account while calculating the known positions 214 of the subareas 504 of the active areas 304A for the radiation operations 140 corresponding to the first direction 116A and second direction 116B. In some embodiments, the reticles 110A and 110B are separate from each other, and the subareas 504A and 504B of each active area 304 partially overlap each other.

In some embodiments, the reticles 110A and 110B are integrated on a reticle 110. Referring to FIG. 7A, the reticle 110 is shifted to be aligned with incoming radiation provided by the radiation source 108A that has a fixed location and orientation. The known positions 214 corresponding to the subareas 504 to be exposed are shifted, and a radiation control signal is generated accordingly to enable radiation operations 140. Conversely, referring to FIG. 7A, the reticle 110 is fixed, and incoming radiation provided by the radiation source 108A is shifted from the reticle 110A to the reticle 110B. The known positions 214 corresponding to the subareas 504 to be exposed are shifted, and a radiation control signal is generated accordingly to enable radiation operations 140.

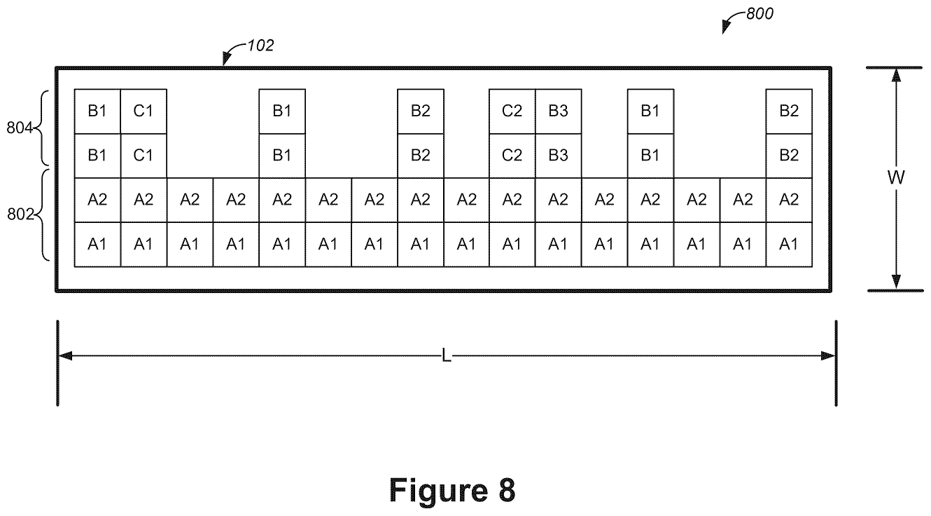

FIG. 8 is a top view 800 of an example substrate 102 having a large aspect ratio, and being processed by the processing system 100, in accordance with some embodiments. The substrate 102 has a width W and a length L. In some situations, a ratio of the length L and the width W is greater than a threshold ratio (e.g., 20). Further, in an example, the length L is greater than 300 mm, e.g. 3,200 mm and width is for example 100 mm. The radiation system 104 moves along the longer dimension (e.g. length L), while substrate 102 moves along the smaller dimension (e.g. width W). Moving the radiation system along the length L significantly reduces the overall size of the processing system 100. Moving the substrate 102 instead of a radiation system 104 along the width W avoids putting a radiation system 104 on two stacked-up motion stages, resulting in a lower center of gravity, reduced dynamic moments, higher stiffness, shorter settling times and better overall stability. The substrate 102 includes a plurality of repeated active areas 802 and a plurality of varying active areas 804. From a different perspective, a plurality of active areas 304 are arranged along the length L of the substrate, and each active areas 304 includes one or more repeated areas 802 and one or more varying areas 804. Repeated areas 802 and varying areas 804 can be stacked adjacent to each other with or without gap, be interleaved with each other with or without gap and in any order. Each repeated area 802 and varying area 804 can be further comprised of a number of partially overlapping subareas. The repeated active areas or subareas 802 are repeated along a respective direction. The varying active areas or subareas 804 include continuous pseudorandom patterns, periodic patterns with gaps such as reference marks or distance coded reference marks shown on FIG. 6D, serial numbers, or any other patterns of similar nature. It is noted that FIG. 8 is an example of patterns formed on a substrate and is not intended to limit this invention to this example.

In some embodiments, a reticle 110 is applied with a to create the repeated active areas 802, and a PSRM 112 is applied to create the varying active areas 804 without using the reticle 110. Each subarea of the varying area 804 is defined based on respective image data loaded onto the PSRM 112 for a respective radiation operation 140 associated with the varying area 804. In some embodiments a PSRM 112 is applied to create both varying active areas 804 and repeated active areas 802. In some embodiments, a reticle 110 includes a plurality of distinct pattern 110a, 110b, etc., and is applied to create both varying active areas 804 and repeated active areas 802. In some embodiments

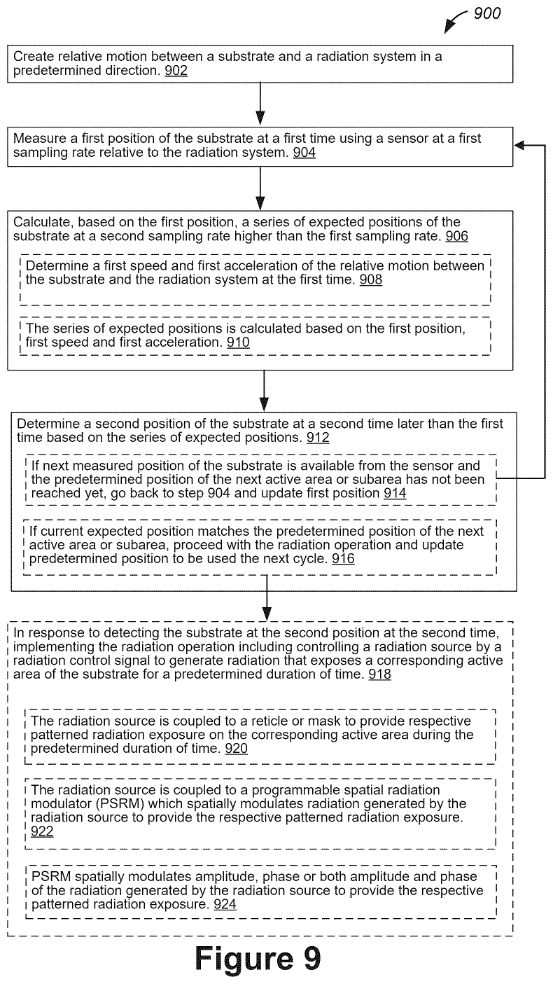

FIG. 9 is a flow diagram of an example lithographic irradiation method 900, in accordance with some embodiments. The method 900 is implemented at an apparatus (e.g., a substrate 102 processing system 100) for controlling a manufacturing process. The apparatus creates (operation 902) relative motion between a substrate 102 and a radiation system 104 in a predetermined direction 116, and repeatedly measures and updates (operation 904) a first position Pᵢ(308) of the substrate 102, relative to the radiation system, at a first time t₁ using a sensor 124 at a first sampling rate f₁. In some embodiments, the sensor 124 measures the first position 308 and one or more additional positions of the substrate 102 from a fixed portion 310 of the substrate 102 (FIG. 3) at the first sampling rate f₁. Based on the first position 308, the apparatus generates (operation 906) a series of expected positions 210 of the substrate 102 at a second sampling rate f₂ higher than the first sampling rate f₁. The apparatus attempts to determine (operation 912) a second position 306 of the substrate 102 at a second time t₂ later than the first time t₁ based on the series of expected positions 210 and a known position 214 of the next active area 304 or subarea 504. If next measured position of the substrate is available from the sensor 124 and the predetermined position 214 of the next active area or subarea has not been reached yet (operation 914), first position P₁ (308) is updated to the latest position measured by sensor 124. If current expected position 210 matches the predetermined position 214 of the next active area or subarea (operation 916), the substrate 102 is configured to be processed (operation 910) by a radiation operation 140 at the second time t₂.

In some embodiments, the first position 308 of the substrate 102 is measured with respect to the radiation system 104. The apparatus determines (operation 908) at least one of a first speed and a first acceleration of the relative motion between the substrate 102 and the radiation system 104 at the first time t₁. The series of expected positions 210 are calculated (operation 910) based on the first position 308 and the at least one of the first speed and the first acceleration. In some embodiments, the series of expected positions 210 are calculated based on the first position 308, and the first speed. In some embodiments, the series of expected positions 210 are calculated based on the first position 308, the first speed, the first acceleration, and a first jerk.

In some embodiments, the apparatus creates the relative motion further includes at least one of: driving the substrate 102 to move in the predetermined direction 116 and driving the radiation system 104 to move in an opposite direction of the predetermined direction 116.

In some embodiments, the substrate 102 has a plurality of active areas 304 (FIG. 3A) that are aligned along a straight line 302A substantially parallel to the predetermined direction 116. The apparatus determines the second position 306 of the substrate 102 by, for each of the series of expected positions 210, determining whether the respective expected position 210 matches one of a plurality of known positions 214 in the predetermined direction 116, and in accordance with a determination that the respective expected position matches a respective known position, identifying the respective expected position 210 as the second position 306 and identifying the second time t₂ that is later than the first time t₁ and corresponds to the second position 306 (FIG. 3B).

In some embodiments, in response to detecting the substrate 102 at the second position 306 at the second time t₂, the apparatus implements the radiation operation 140 (operation 918) by controlling a radiation source (e.g., coupled to a reticle 110, or coupled to a PSRM 112) by a radiation control signal to generate radiation that exposes a corresponding active area 304C of the substrate 102, for a predetermined duration of time, to radiation which has been spatially modulated in terms of at least one of an amplitude and phase. The duration of time has a predefined temporal length. Additionally, in some embodiments, the radiation source 108A is coupled to a reticle 110 configured to modulate the substantially uniform illumination 140 according to a pattern, thereby forming a pattern of radiation exposure on the corresponding active area 304C during the predetermined duration of time (operation 920). In some embodiments, the radiation source 108A provides substantially uniform illumination 140 to the reticle 110 during the predetermined duration of time. In some embodiments, the pattern of the reticle is scaled down by a scale factor to form the pattern of radiation exposure on the corresponding active area.

In some embodiments, the reticle 110 includes at least two distinct subareas 504 (e.g., 504A and 504B in FIG. 5B), and each subarea 504 is independently shifted into a radiation path 120 to define a respective pattern of radiation exposure on the respective subarea 504 without requiring a separate reticle.

In some embodiments, the radiation source 108B is coupled to a programmable spatial radiation modulator (PSRM) 112 configured to spatially modulate the substantially uniform illumination according to a programmed pattern, thereby forming a spatially modulated radiation exposure 126 on the corresponding active area 304 during the duration of time. The PSRM spatially modulates at least one of an amplitude and a phase of radiation 140 generated by the radiation source 108B to provide the respective spatially-modulated radiation exposure 126.

In some embodiments, the radiation source provides respective spatially-modulated radiation exposure on the corresponding active area 304C during the predetermined duration of time, and the radiation source includes a light source and is couple to a PSRM (operation 922). The PSRM spatially modulates amplitude, phase or both amplitude and phase (operation 924) of the light generated by the light source to provide the respective patterned radiation exposure (FIG. 4B). In some embodiments, the radiation source 108B provides substantially uniform illumination to the PSRM 112 during the predetermined duration of time. In some embodiments, a pattern of the PSRM is scaled down by a scale factor to form a pattern of the respective spatially-modulated radiation exposure on the corresponding active area.

In some embodiments, the substrate 102 has a plurality of active areas 304 that are aligned along a straight line 502 (FIG. 5A) substantially parallel to the predetermined direction 116, and each active area 304 includes at least two subareas, e.g. first subarea 504A and a second subarea 504B (FIG. 5B). Each of the plurality of subareas 504 of the substrate 102 is configured to be processed by the radiation operation 140 at the second time t₂ synchronized with the alignment of the radiation system 104 with a corresponding subarea 504. Further, in some embodiments, while the substrate 102 moves along a first direction 116 (FIG. 5D), the apparatus successively controls a radiation source to provide radiation exposure on the first subarea 504A of each active area 304 of the substrate 102. While the substrate 102 moves along a second direction 116B, the apparatus successively controls the radiation source to provide radiation exposure on the second subarea 504B of each active area 304 of the substrate 102. Additionally, in some embodiments (FIGS. 5A-8), the first subarea 504A and the second subarea 504B are connected to each other without any gap, separated from each other by a gap, or partially overlap with one another and an overlapped area is exposed to the scaled and spatially-modulated radiation 126 of the radiation source 108A or 108B at least twice, each time with a unique pattern

In some embodiments, the substrate 102 has a plurality of known positions 214 each of which corresponds to a respective active area 304 of the substrate 102. When the substrate 102 reaches each known position 214, the respective active area 304 is aligned with a fixed location of a radiation system 104, and is configured to be exposed to radiation 126 (FIG. 1) generated by the radiation system 104. Further, in some embodiments, the plurality of known positions 214 includes a first known position and a second known position. In accordance with a determination that the second position 306 matches the first known positions 214A (FIG. 3B), the apparatus controls a first radiation source (e.g., a PSRM 112 in FIG. 4B) to provide a first pattern of radiation exposure on a first active area 304A of the substrate 102. In accordance with a determination that the second position 306 matches the second known position 214B, the apparatus controls the first radiation source to provide a second pattern of radiation exposure on a second active area 304B of the substrate 102. The first pattern is distinct form the second pattern.

In some embodiments, the plurality of known positions 214 includes a first known position. In accordance with a determination that the second position 306 matches the first known position, the apparatus (1) controls a first radiation source 108A or 108B by a first radiation control signal to provide a fixed pattern of radiation exposure on a first subarea 504A (FIGS. 6A and 6B) of a first active area 304A of the substrate 102 and (2) controls a second radiation source 108A or 108B by a second radiation control signal to provide a first pattern of radiation exposure on a second subarea 504B (FIGS. 6A and 6B) of the first active area 304 of the substrate 102. Further, in some embodiments, the plurality of known positions 214 further includes a second known position. In accordance with a determination that the second position 306 matches the second known positions 214, the apparatus (1) controls the first radiation source 108A or 108B by the first radiation control signal to provide the fixed pattern of radiation exposure on a first subarea 504A of a second active area 304B of the substrate 102, and (2) controls the second radiation source 108A or 108B by the second radiation control signal to provide a second pattern of radiation exposure on a second subarea 504B of the second active area 304B of the substrate 102 (FIGS. 6A and 6B). The first pattern is distinct form the second pattern.

Memory is also used to store instructions and data associated with the method 900, and includes high-speed random-access memory, such as SRAM, DDR DRAM, or other random access solid state memory devices; and, optionally, includes non-volatile memory, such as one or more magnetic disk storage devices, one or more optical disk storage devices, one or more flash memory devices, or one or more other non-volatile solid state storage devices. The memory, optionally, includes one or more storage devices remotely located from one or more processing units. Memory, or alternatively the non-volatile memory within memory, includes a non-transitory computer readable storage medium. In some embodiments, memory, or the non-transitory computer readable storage medium of memory, stores the programs, modules, and data structures, or a subset or superset for implementing method 900. Alternatively, in some embodiments, the electronic system implements the method 900 at least partially based on a MCU, SOC, FPGA or ASIC.

Each of the above identified elements may be stored in one or more of the previously mentioned memory devices, and corresponds to a set of instructions loaded by a controller 118 for performing a function described above. The above identified modules or programs (i.e., sets of instructions) need not be implemented as separate software programs, procedures, modules or data structures, and thus various subsets of these modules may be combined or otherwise re-arranged in various embodiments. In some embodiments, the memory, optionally, stores a subset of the modules and data structures identified above. Furthermore, the memory, optionally, stores additional modules and data structures not described above.

The terminology used in the description of the various described implementations herein is for the purpose of describing particular implementations only and is not intended to be limiting. As used in the description of the various described implementations and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. A method for lithographic irradiation, comprising:
creating relative motion between a substrate and a radiation system in a predetermined direction;
measuring a first position of the substrate relative to the radiation system at a first time using a sensor at a first sampling rate;
generating, based on the first position, a series of expected positions of the substrate at a second sampling rate higher than the first sampling rate; and
determining a second position of the substrate at a second time later than the first time based on the series of expected positions, wherein the substrate is configured to be processed by a radiation operation at the second time.

2. The method of claim 1, wherein the first position of the substrate is measured with respect to the radiation system, the method further comprising:
determining at least one of a first velocity and a first acceleration of the relative motion between the substrate and the radiation system at the first time, wherein the series of expected positions are generated based on the first position and the at least one of the first speed and the first acceleration.

3. The method of claim 1, wherein creating the relative motion further comprises:
driving the radiation system to move in the predetermined direction; and
driving the substrate to move in another direction that is orthogonal to the predetermined direction; and
wherein the substrate has a dimension in the direction substantially parallel to the predetermined direction that is substantially larger than a dimension of the substrate in the direction substantially parallel to the direction that is orthogonal to the predetermined direction.

4. The method of claim 1, wherein the substrate has a plurality of active areas that are aligned along a straight line substantially parallel to the predetermined direction, and determining the second position of the substrate further comprises, for each of the series of expected positions:
determining whether the respective expected position matches one of a plurality of known positions in the predetermined direction; and
in accordance with a determination that the respective expected position matches a respective known position, identifying the respective expected position as the second position and identifying the second time that is later than the first time and corresponds to the second position.

5. The method of claim 1, further comprising:
in response to detecting the substrate at the second position at the second time, implementing the radiation operation including controlling a radiation source by a radiation control signal to generate radiation that exposes a corresponding active area of the substrate for a predetermined duration of time to radiation which has been spatially modulated in terms of at least one of an amplitude and phase.

6. The method of claim 5, wherein a position accuracy level and an edge roughness level of a feature produced on the substrate by the radiation operation is defined based on a temporal length of the predetermined duration of time and a speed of the substrate.

7. The method of claim 5, wherein the radiation source provides substantially uniform illumination corresponding to the corresponding active area during the predetermined duration of time.

8. The method of claim 7, wherein the radiation source is coupled to a reticle configured to modulate the substantially uniform illumination according to a pattern of the reticle, thereby forming a pattern of radiation exposure on the corresponding active area during the duration of time.

9. The method of claim 8, wherein the pattern of the reticle is scaled down by a scale factor to form the pattern of radiation exposure on the corresponding active area.

10. The method of claim 9, wherein the reticle includes at least two distinct subareas, and each subarea is independently shifted into a radiation path to define a respective pattern of radiation exposure on the respective subarea without requiring a separate reticle.

11. The method of claim 7, wherein the radiation source is coupled to a programmable spatial radiation modulator (PSRM) configured to spatially modulate the substantially uniform illumination according to a programmed pattern, thereby forming a spatially modulated radiation exposure on the corresponding active area during the duration of time, the method further comprising:
at the PSRM, spatially modulating at least one of an amplitude and a phase of radiation generated by the radiation source to provide the respective spatially-modulated radiation exposure.

12. The method of claim 11, wherein a pattern of the PSRM is scaled down by a scale factor to form a pattern of the respective spatially-modulated radiation exposure on the corresponding active area.

13. The method of claim 1, wherein the substrate has a plurality of active areas that are aligned along a straight line substantially parallel to the predetermined direction, and each active area includes a first subarea and a second subarea, and wherein one of the plurality of active areas of the substrate is configured to be processed by the radiation operation at the second time.

14. The method of claim 13, further comprising:
while the substrate moves along a first direction, successively controlling a radiation source to provide radiation exposure on the first subarea of each active area of the substrate; and
while the substrate moves along a second direction, successively controlling the radiation source to provide radiation exposure on the second subarea of each active area of the substrate.

15. The method of claim 14, wherein the first subarea and the second subarea partially overlap with one another, and an overlapped area is exposed to the spatially-modulated radiation exposure of the radiation source at least twice.

16. The method of claim 1, wherein the substrate has a plurality of known positions each of which corresponds to a respective active area of the substrate, and when the substrate reaches each known position, the respective active area is aligned with a fixed location of a radiation system, and is configured to be exposed to radiation generated by the radiation system.

17. The method of claim 16, wherein the plurality of known positions includes a first known position and a second known position, the method further comprising:
in accordance with a determination that the second position matches the first known positions controlling a first radiation source to provide a first pattern of radiation exposure on a first active area of the substrate; and
in accordance with a determination that the second position matches the second known position, controlling the first radiation source to provide a second pattern of radiation exposure on a second active area of the substrate, wherein the first pattern is distinct form the second pattern.

18. The method of claim 16, wherein the plurality of known positions includes a first known position, the method further comprising:
in accordance with a determination that the second position matches the first known position, (1) controlling a first radiation source by a first radiation control signal to provide a fixed pattern of radiation exposure on a first subarea of a first active area of the substrate and (2) controlling a second radiation source by a second radiation control signal to provide a first pattern of radiation exposure on a second subarea of the first active area of the substrate.

19. The method of claim 18, wherein the plurality of known positions further includes a second known position, the method further comprising:
in accordance with a determination that the second position matches the second known positions, (1) controlling the first radiation source by the first radiation control signal to provide the fixed pattern of radiation exposure on a first subarea of a second active area of the substrate, and (2) controlling the second radiation source by the second radiation control signal to provide a second pattern of radiation exposure on a second subarea of the second active area of the substrate wherein the first pattern is distinct form the second pattern.

20. An apparatus, comprising:
a sensor; and
a controller coupled to the sensor, wherein the controller is configured to:
create relative motion between a substrate and a radiation system in a predetermined direction;
control the sensor to measure a first position of a substrate relative to the radiation system at a first time at a first sampling rate;
generate, based on the first position, a series of expected positions of the substrate at a second sampling rate higher than the first sampling rate; and
determine a second position of the substrate at a second time later than the first time based on the series of expected positions, wherein the substrate is configured to be processed by a radiation operation at the second time.
